(19) United States
(12) Patent Application Publication
(10) Pub. No.: US 2009/0311871 A1
(43) Pub. Date: Dec. 17, 2009

(54) ORGANIC ARC ETCH SELECTIVE FOR IMMERSION PHOTORESIST

(75) Inventors: Helen H. Zhu, Fremont, CA (US); Peter Cirigliano, Sunnyvale, CA (US); S. M. Reza Sadjadi, Saratoga, CA (US)

Correspondence Address: Beyer Law Group LLP, P.O. BOX 1687, Cupertino, CA, 95015-1687, US

(73) Assignee: LAM RESEARCH CORPORATION, Fremont, CA (US)

(21) Appl. No.: 12/139,124

(22) Filed: Jun. 13, 2008

(51) Int. Cl. H01L 21/302

(52) U.S. Cl. 438/725; 156/345.25; 257/E21.214

(57) ABSTRACT

A method for forming etch features in an etch layer over a substrate and below an organic ARC layer, which is below an immersion lithography photoresist mask is provided. The substrate with the etch layer, organic ARC layer, and immersion lithography photoresist mask is placed into a processing chamber. The organic ARC layer is opened. The organic ARC layer opening comprises flowing an organic ARC open gas mixture into the processing chamber, wherein the organic ARC open gas mixture comprises an etchant gas and a polymerization gas comprising CO, forming an organic ARC open plasma from the organic ARC open gas mixture, etching the organic ARC layer with the organic ARC open plasma until the organic ARC layer is opened, and stopping the flow of organic ARC open gas mixture into the processing chamber before the etch layer is completely etched.

### BACKGROUND OF THE INVENTION

1. Field of the Invention

The invention relates to semiconductor devices. More specifically, the invention relates to the production of semiconductor devices which require and etch using a patterned mask formed using immersion lithography over an organic anti-reflective coating (ARC).

2. Description of the Related Art

In the formation of semiconductor devices, photolithographic techniques are used to illuminate and then pattern photoresist. Immersion lithography replaces a usual air gap between a final lens and the photoresist surface with a liquid medium with an index of refraction that is greater than one. This results in a lithographic resolution that is increased by a factor that is equal to the refractive index of the liquid.

### SUMMARY OF THE INVENTION

To achieve the foregoing and in accordance with the purpose of the present invention, a method for forming etch features in an etch layer over a substrate and below an organic ARC layer, which is below an immersion lithography photoresist mask is provided. The substrate with the etch layer, organic ARC layer, and immersion lithography photoresist mask is placed into a processing chamber. The organic ARC layer is opened. The organic ARC layer opening comprises flowing an organic ARC open gas mixture into the processing chamber, wherein the organic ARC open gas mixture comprises an etchant gas and a polymerization gas comprising CO, forming an organic ARC open plasma from the organic ARC open gas mixture, etching the organic ARC layer with the organic ARC open plasma until the organic ARC layer is opened, and stopping the flow of organic ARC open gas mixture into the processing chamber before the etch layer is completely etched.

In another manifestation of the invention, a method for forming etch features in an etch layer over a substrate and below an organic ARC layer, which is below an immersion lithography photoresist mask is provided. The substrate with the etch layer, organic ARC layer, and immersion lithography photoresist mask is placed into a processing chamber. The organic ARC layer is opened, comprising the steps of flowing an organic ARC open gas mixture into the processing chamber, wherein the organic ARC open gas mixture comprises an etchant gas comprising N₂ and H₂ and a polymerization gas comprising CO and CH₃F, forming an organic ARC open plasma from the organic ARC open gas mixture, etching the organic ARC layer with the organic ARC open plasma until the organic ARC layer is opened, and stopping the flow of organic ARC open gas mixture into the processing chamber before the etch layer is completely etched. The etch layer is etched after stopping the flow of the organic ARC open gas mixture, using the immersion lithography photoresist as an etch mask. The substrate is removed from the processing chamber, so that the opening the organic ARC layer and etching the etch layer are done in situ or ex-situ.

In another manifestation of the invention an apparatus for etching features in an etch layer, wherein the etch layer is supported by a substrate and wherein the etch layer is covered by an organic ARC layer, which is below an immersion lithography photoresist mask with mask features is provided. A plasma processing chamber is provided, comprising a chamber wall forming a plasma processing chamber enclosure, a substrate support for supporting a wafer within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure. A gas source is in fluid connection with the gas inlet an etchant gas source and a CO polymerization gas source. A controller is controllably connected to the gas source and the at least one electrode and comprises at least one processor and computer readable media. The computer readable media comprises computer readable code for opening the organic ARC layer, comprising computer readable code for flowing an organic ARC open gas mixture into the processing chamber, wherein the organic ARC open gas mixture comprises an etchant gas and a polymerization gas comprising CO, computer readable code for forming an organic ARC open plasma from the organic ARC open gas mixture, computer readable code for etching the organic ARC layer with the organic ARC open plasma until the organic ARC layer is opened, and computer readable code for stopping the flow of organic ARC open gas mixture into the processing chamber before the etch layer is completely etched and computer readable code for etching the etch layer.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart for forming a feature in an etch layer.

FIGS. 2A-C are cross-sectional views of an etch layer over a substrate during the formation of features using the inventive ARC open process.

FIG. 3 is a more detailed flow chart of a step of the opening of the organic ARC layer.

FIG. 4 is a schematic view of a process chamber that may be used in a preferred embodiment of the invention.

FIGS. 5A and 5B illustrate a computer system, which is suitable for implementing a controller.

FIGS. 6A-B photos from an example of an embodiment of the invention

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

In immersion lithography process, a soft photoresist may result. Such a photoresist layer easily erodes when opening an underlying organic ARC. It is desirable to have a method that is able to open or etch an organic ARC, while minimizing the erosion of the immersion lithography photoresist layer.

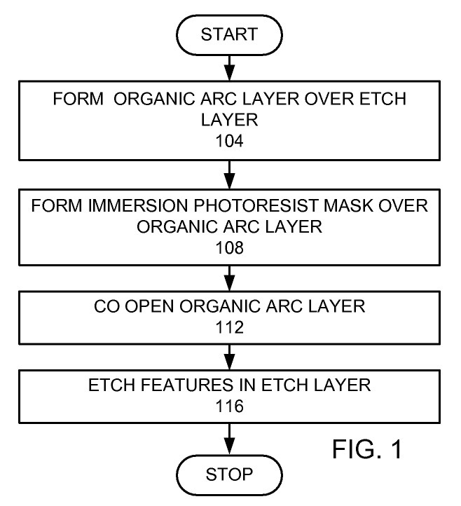

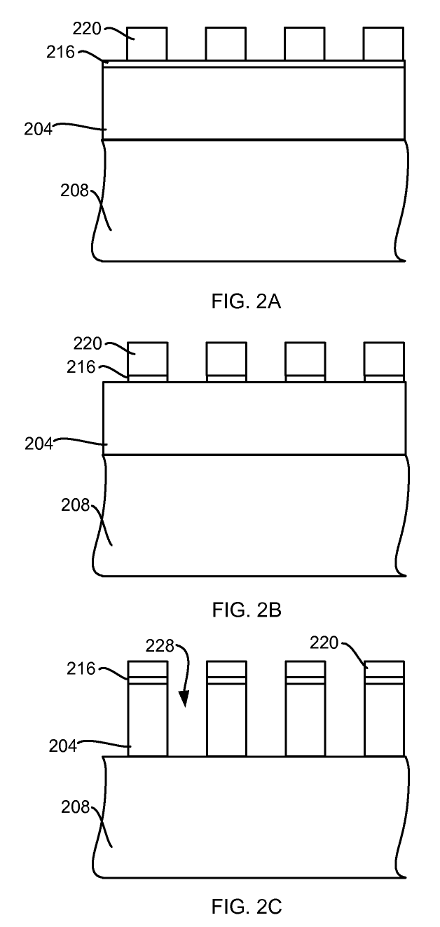

To facilitate understanding, FIG. 1 is a high level flow chart for forming a feature in an etch layer, which uses the inventive antireflective coating (ARC) open process. An organic ARC layer is formed over an etch layer, which is a layer to be etched (step 104). FIG. 2A is a cross-sectional view of an etch layer 204 over a substrate 208. An organic ARC layer 216 has been formed over the etch layer 204. An immersion lithography photoresist mask 220 is formed over the ARC layer 216 (step 108). The organic ARC layer is opened with a CO process (step 112). FIG. 2B is a cross-sectional view of the organic ARC layer 216 after it is opened. Features 228 are then etched into the etch layer 204 through the photoresist mask 220 and the organic ARC layer 216, as shown in FIG. 2C. The photoresist mask 220 and organic ARC layer 216 may be completely removed during a subsequent photoresist stripping process.

Although the etch layer 204 is shown as being on top of the substrate 208, one or more layers may be between the etch layer 204 and the substrate 208. Alternatively, the substrate may be the etch layer. In addition, one or more layers may be between the etch layer 204 and the ARC layer 216. The etch layer may be a conductive layer or a dielectric layer. The etch layer may be an organic layer, such as amorphous carbon.

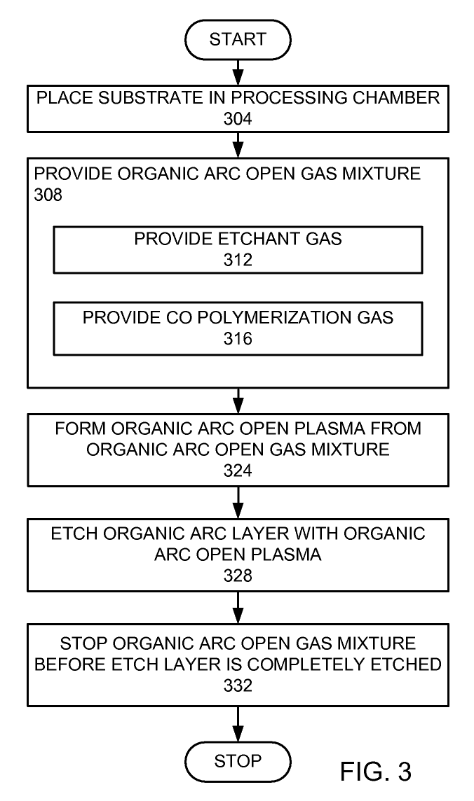

FIG. 3 is a more detailed flow chart of the step of a CO opening of the organic ARC layer (step 112). The substrate is placed in a processing chamber (step 304). An organic ARC open gas mixture is provided into the processing chamber (step 308). This step comprises providing an etchant gas to the processing chamber (step 312) and providing a CO containing polymerization gas to the processing chamber (step 316). In this embodiment, the polymerization gas is CO and CH₃F. The organic ARC open gas mixture is formed into an organic ARC open plasma (step 324). The organic ARC layer is etched or opened by the organic ARC open plasma (step 328). The organic ARC open gas mixture is stopped before the etch layer is completely etched (step 332). This process may cause some etching of the etch layer if the etch layer is organic such as a-Carbon, but this process is not designed to be the main etch for the etch layer.

### EXAMPLE

In an example of the invention, the etch layer 204 is a silicon oxide dielectric layer over a silicon wafer substrate 208. The organic ARC layer is a bottom antireflective coating (BARC), which is an organic ARC material. It is preferred that BARC be similar to photoresist, so that the BARC has similar stripping characteristics. Because of the similarities between BARC and immersion lithography photoresist and because of the additional softness of immersion lithography photoresist, it is difficult to find a recipe to open a BARC layer without significantly eroding the immersion lithography photoresist. In other embodiments, the ARC layer may be made of other organic materials to form an organic ARC layer. In this example, the organic ARC is the ARC® series of the 193 nm product from Brewer Science. The photoresist mask 220 is made of an immersion lithography photoresist. Preferably the immersion lithography photoresist mask is a 193 nm and higher generation photoresist. Such immersion lithography photoresists are softer than non immersion lithography photoresist, and therefore erode much more easily than non immersion lithography photoresist.

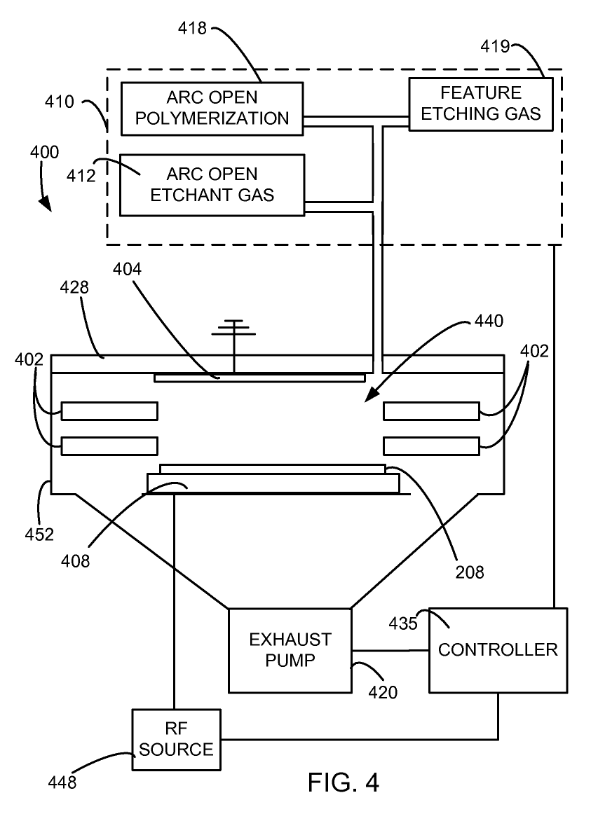

FIG. 4 is a schematic view of a plasma processing chamber 400 that may be used for opening the organic ARC layer and etching the features in this example. The plasma processing chamber 400 comprises confinement rings 402, an upper electrode 404, a lower electrode 408, a gas source 410, and an exhaust pump 420. For the organic ARC opening step, the gas source 410 comprises an organic ARC open etchant gas source 412, an organic ARC CO open polymerization gas source 418, and a gas source for etching features in the etch layer 419, if the features are etched in the same process chamber. The gas source 410 may comprise additional gas sources. Within plasma processing chamber 400, the substrate 208 is positioned upon the lower electrode 408. The lower electrode 408 incorporates a suitable substrate chucking mechanism (e.g., electrostatic, mechanical clamping, or the like) for holding the substrate 208. The reactor top 428 incorporates the upper electrode 404 disposed immediately opposite the lower electrode 408. The upper electrode 404, lower electrode 408, and confinement rings 402 define the confined plasma volume 440. Gas is supplied to the confined plasma volume 440 by the gas source 410 and is exhausted from the confined plasma volume 440 through the confinement rings 402 and an exhaust port by the exhaust pump 420. An RF source 448 is electrically connected to the lower electrode 408. The upper electrode 404 is grounded. Chamber walls 452 surround the confinement rings 402, the upper electrode 404, and the lower electrode 408. The RF source 448 may comprise a 27 MHz power source and a 2 MHz power source, and a 60 MHz power source. An Exelan 2300™, which is made by LAM Research Corporation™ of Fremont, Calif., was used in this example of the invention. Different combinations of connecting RF power to the electrode are possible in other embodiments, such as having an RF source connected to the upper electrode 404.

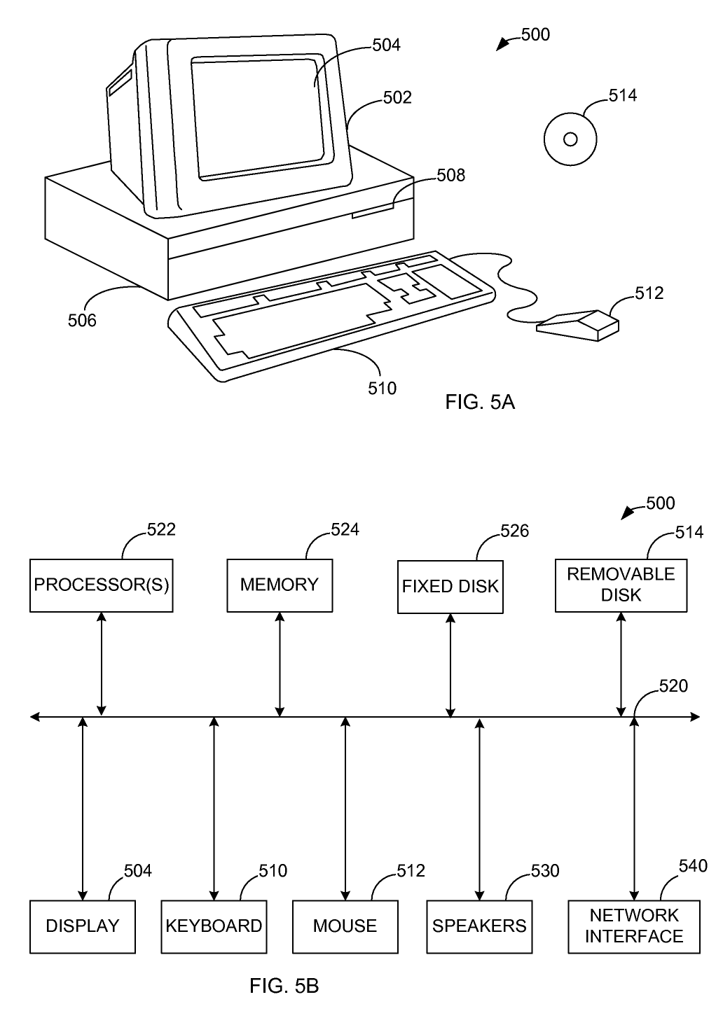

FIGS. 5A and 5B illustrate a computer system 500, which is suitable for implementing a controller 435 used in embodiments of the present invention. FIG. 5A shows one possible physical form of the computer system. Of course, the computer system may have many physical forms ranging from an integrated circuit, a printed circuit board, and a small handheld device up to a huge super computer. Computer system 500 includes a monitor 502, a display 504, a housing 506, a disk drive 508, a keyboard 510, and a mouse 512. Disk 514 is a computer-readable medium used to transfer data to and from computer system 500.

FIG. 5B is an example of a block diagram for the computer system 500. Attached to system bus 520 is a wide variety of subsystems. Processor(s) 522 (also referred to as central processing units or CPUs) are coupled to storage devices, including memory 524. Memory 524 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 526 is also coupled bi-directionally to CPU 522; it provides additional data storage capacity and may also include any of the computer-readable media described below. Fixed disk 526 may be used to store programs, data, and the like and is typically a secondary storage medium (such as a hard disk) that is slower than primary storage. It will be appreciated that the information retained within fixed disk 526 may, in appropriate cases, be incorporated in standard fashion as virtual memory in memory 524. Removable disk 514 may take the form of any of the computer-readable media described below.

CPU 522 is also coupled to a variety of input/output devices, such as display 504, keyboard 510, mouse 512 and speakers 530. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 522 optionally may be coupled to another computer or telecommunications network using network interface 540. With such a network interface, it is contemplated that the CPU might receive information from the network, or might output information to the network in the course of performing the above-described method steps. Furthermore, method embodiments of the present invention may execute solely upon CPU 522 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

Preferably, the organic ARC open etchant gas comprises H₂ and N₂. Preferably the CO polymerization gas comprises CO and CH₃F. In this example, the organic ARC open etchant gas comprises 75 sccm N₂ and 50 sccm H₂. The organic ARC open CO polymerization gas comprises 150 sccm CO and 10 sccm CH₃F. The chamber pressure is set to 150 mTorr. The power provided by the lower electrode is at 27 MHz and/or 60 MHz with no power provided at 2 MHz. The power provided during this step is kept low to reduce the removal of any of the photoresist mask 220. This organic ARC open gas mixture which uses H₂ and N₂ as the ARC open etchant gases is highly selective for etching BARC with respect to the immersion lithography photoresist. This high selectivity is defined as being greater than 5:1. Preferably, the lower electrode is kept at a temperature between −20° and 40° C.

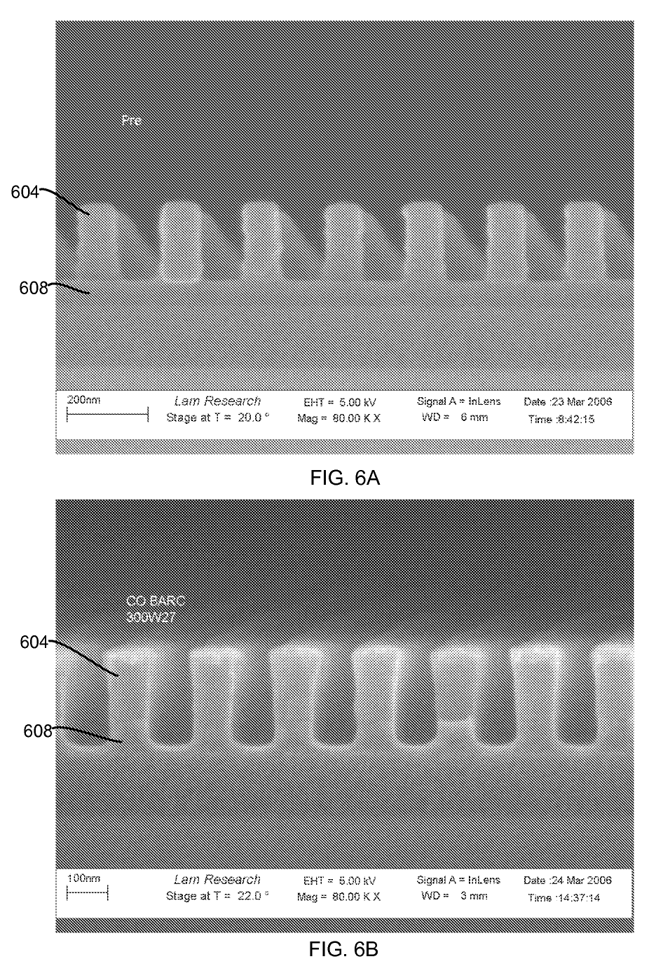

FIG. 6A is photograph of a cross-sectional view of an immersion lithography photoresist mask 604 over an organic ARC layer 608 after the immersion photoresist process and before the organic ARC open. FIG. 6B is a photograph of a cross-sectional view after the organic ARC 608 has been etched (a partial ARC etch is shown here for etch rate calculation purpose). It should be noted that the immersion lithography photoresist mask 604 remains intact and had close to zero loss after the organic ARC open.

It was unexpected that such a process would be successful in reducing erosion of an immersion lithography photoresist mask, while opening an organic ARC layer. It was the speculation of the inventors that this method will also work with O2 based ARC open chemistries to achieve similar results.

Table 1 provides preferred, more preferred, and most preferred ranges for the open etch.

TABLE 1

| | Preferred Range | More Preferred | Most Preferred |
|---|---|---|---|
| N₂ | 30-110 sccm | 50-90 sccm | 60-80 sccm |
| H₂ | 20-80 sccm | 30-70 sccm | 40-60 sccm |
| CO | 50-500 sccm | 100-400 sccm | 150-300 sccm |
| CH₃F | 1-25 sccm | 5-20 sccm | 4-15 sccm |
| 27 MHz Power | 0-1000 Watts | 0-800 Watts | 0-400 Watts |
| 2 MHz Power | 0-1500 Watts | 0-1000 Watts | 100-600 Watts |
| Pressure | 50-500 mTorr | 100-400 mTorr | 200-300 mTorr |
| Flow ratio | 150:1-30:1 | 100:1-20:1 | 50:1-10:1 |
| CO:CH₃F | | | |
| Temperature | −20° C.-+60 C. | −10 C-+40° C. | 20° C. |

While this invention has been described in terms of several preferred embodiments, there are alterations, permutations, modifications and various substitute equivalents, which fall within the scope of this invention. It should also be noted that there are many alternative ways of implementing the methods and apparatuses of the present invention. It is therefore intended that the following appended claims be interpreted as including all such alterations, permutations, modifications, and various substitute equivalents as fall within the true spirit and scope of the present invention.

What is claimed is:

1. A method for forming etch features in an etch layer over a substrate and below an organic ARC layer, which is below an immersion lithography photoresist mask, comprising:
placing the substrate with the etch layer, organic ARC layer, and immersion lithography photoresist mask into a processing chamber; and
opening the organic ARC layer, comprising:
flowing an organic ARC open gas mixture into the processing chamber, wherein the organic ARC open gas mixture comprises:
an etchant gas; and
a polymerization gas comprising CO;
forming an organic ARC open plasma from the organic ARC open gas mixture;
etching the organic ARC layer with the organic ARC open plasma until the organic ARC layer is opened; and
stopping the flow of organic ARC open gas mixture into the processing chamber before the etch layer is completely etched.

2. The method, as recited in claim 1, wherein the polymerization gas further comprises CH₃F.

3. The method, as recited in claim 2, the etchant gas comprises N₂ and H₂.

4. The method, as recited in claim 3, further comprising etching the etch layer after stopping the flow of the organic ARC open gas mixture.

5. The method, as recited in claim 4, wherein the etching the etch layer uses the immersion lithography photoresist as an etch mask for etching the etch layer.

6. The method, as recited in claim 5, wherein the organic ARC is BARC.

7. The method, as recited in claim 6, wherein the photoresist mask is of a 193 or higher generation immersion lithography photoresist.

8. The method, as recited in claim 7, wherein the organic ARC opening has a selectivity of 5:1 with respect to the immersion lithography photoresist.

9. The method, as recited in claim 4, further comprising removing the substrate from the processing chamber after the etching the etch layer, so that the opening the organic ARC layer and etching the etch layer are done in situ.

10. The method, as recited in claim 1, the etchant gas comprises N₂ and H₂.

11. The method, as recited in claim 1, further comprising etching the etch layer after stopping the flow of the organic ARC open gas mixture.

12. The method, as recited in claim 11, wherein the etching the etch layer uses the immersion lithography photoresist as an etch mask for etching the etch layer.

13. The method, as recited in claim 11, further comprising removing the substrate from the processing chamber after the etching the etch layer, so that the opening the organic ARC layer and etching the etch layer are done in situ.

14. The method, as recited in claim 1, wherein the organic ARC is BARC.

15. The method, as recited in claim 1, wherein the photoresist mask is of a 193 or higher generation immersion lithography photoresist.

16. The method, as recited in claim 1, wherein the organic ARC opening has a selectivity of 5:1 with respect to the immersion lithography photoresist.

17. A method for forming etch features in an etch layer over a substrate and below an organic ARC layer, which is below an immersion lithography photoresist mask, comprising:
placing the substrate with the etch layer, organic ARC layer, and immersion lithography photoresist mask into a processing chamber;
opening the organic ARC layer, comprising:
flowing an organic ARC open gas mixture into the processing chamber, wherein the organic ARC open gas mixture comprises:
an etchant gas comprising N₂ and H₂; and
a polymerization gas comprising CO and CH₃F;
forming an organic ARC open plasma from the organic ARC open gas mixture;
etching the organic ARC layer with the organic ARC open plasma until the organic ARC layer is opened; and
stopping the flow of organic ARC open gas mixture into the processing chamber before the etch layer is completely etched;
etching the etch layer after stopping the flow of the organic ARC open gas mixture, using the immersion lithography photoresist as an etch mask; and
removing the substrate from the processing chamber, so that the opening the organic ARC layer and etching the etch layer are done in situ.

18. An apparatus for etching features in an etch layer, wherein the etch layer is supported by a substrate and wherein the etch layer is covered by an organic ARC layer, which is below an immersion lithography photoresist mask with mask features, comprising:
a plasma processing chamber, comprising:
a chamber wall forming a plasma processing chamber enclosure;
a substrate support for supporting a wafer within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet, comprising;
an etchant gas source; and
a CO polymerization gas source;
a controller controllably connected to the gas source and the at least one electrode, comprising:
at least one processor; and
computer readable media, comprising:
computer readable code for opening the organic ARC layer, comprising:
computer readable code for flowing an organic ARC open gas mixture into the processing chamber, wherein the organic ARC open gas mixture comprises an etchant gas flowed from the etchant gas source and a polymerization gas comprising CO flowed from the CO polymerization gas source;
computer readable code for forming an organic ARC open plasma from the organic ARC open gas mixture;
computer readable code for etching the organic ARC layer with the organic ARC open plasma until the organic ARC layer is opened; and
computer readable code for stopping the flow of organic ARC open gas mixture into the processing chamber before the etch layer is completely etched; and
computer readable code for etching the etch layer.
